(19) United States
(12) Patent Application Publication
(10) Pub. No.: US 2025/0212442 A1
(43) Pub. Date: Jun. 26, 2025

(54) INTEGRATED CIRCUIT (IC) WITH CORRUGATED CHANNEL STRUCTURES HAVING VERTICALLY SEPARATED SOURCE AND BODY CONTACT REGIONS

(71) Applicant: TEXAS INSTRUMENTS INCORPORATED, Dallas, TX (US)

(72) Inventors: Sheldon Douglas Haynie, Dallas, TX (US); John Arch, Richardson, TX (US)

(21) Appl. No.: 18/391,307

(22) Filed: Dec. 20, 2023

(51) Int. Cl. H01L 29/66; H01L 21/8234; H01L 27/088; H01L 29/08; H01L 29/78

(52) U.S. Cl. CPC H10D 30/024; H10D 30/62; H10D 62/151; H10D 84/0128; H10D 84/0158; H10D 84/038; H10D 84/834

(57) ABSTRACT

An integrated circuit (IC) device including one or more corrugated channel structures formed in or over a semiconductor substrate, where a corrugated channel structure includes a first sidewall surface, a second sidewall surface and a top surface. In an example, the IC device includes a first contact region having a first conductivity type extending into a sidewall surface of the corrugated channel structure and a second contact region having an opposite second conductivity type extending into a horizontal surface adjacent to the sidewall surface.

### FIELD OF THE DISCLOSURE

Disclosed implementations relate generally to the field of integrated circuits (ICs) and IC fabrication. More particularly, but not exclusively, the disclosed implementations relate to an IC device including one or more corrugated channel structures.

### BACKGROUND

FinFETs are a type of three-dimensional (3D) MOSFET transistor where the channel includes a non-planar structure resembling a “fin” and comprises semiconductor material protruding from a semiconductor substrate. FinFETs are regarded as candidates for use in future advanced CMOS technology nodes due to the FinFET's superior gate control over the channel, resulting in faster switching times, improved short-channel effect immunity, higher current densities, and improved Iₒₙ/I_{off} ratios. As the integration of FinFET technologies continues to become more prevalent, demands for improvements in various aspects of the FinFET design are increasing.

### SUMMARY

The following presents a simplified summary in order to provide a basic understanding of some examples of the present disclosure. This summary is not an extensive overview of the examples, and is neither intended to identify key or critical elements of the examples, nor to delineate the scope thereof. Rather, the primary purpose of the summary is to present some concepts of the present disclosure in a simplified form as a prelude to a more detailed description that is presented in subsequent sections further below.

In one example, a method of fabricating an IC device is disclosed. The method may comprise, among others, forming a corrugated channel structure over a semiconductor substrate comprising a substrate material, the corrugated channel structure having a vertical height along a surface normal relative to a top surface of the semiconductor substrate; and forming a first contact region having a first conductivity type extending into a sidewall surface of the corrugated channel structure and a second contact region having an opposite second conductivity type extending into a horizontal surface adjacent to the sidewall surface. In one example, the first contact region may be a body contact region and the second contact region may be a source contact region. In another example, the first contact region may be a source contact region and the second contact region may be a body contact region.

In one example, an IC device is disclosed, which may comprise, among others, a corrugated channel structure over a semiconductor substrate; and a first contact region having a first conductivity type extending into a sidewall surface of the corrugated channel structure and a second contact region having an opposite second conductivity type extending into a horizontal surface adjacent to the sidewall surface.

### BRIEF DESCRIPTION OF THE DRAWINGS

Implementations of the present disclosure are illustrated by way of example, and not by way of limitation, in the Figures of the accompanying drawings. Different references to “an” or “one” implementation in this disclosure are not necessarily to the same implementation, and such references may mean at least one. Further, when a particular feature, structure, or characteristic is described in connection with an implementation, such feature, structure, or characteristic in connection with other implementations may be feasible whether or not explicitly described. Shapes depicted in the drawings attached are simplified for ease of drafting and/or presentation and support of concepts. They do not limit the scope of examples of the present disclosure with respect to size, count, aspect ratio, contour or specific angles and radii of transitions and/or other related features that may be present in an example implementation.

Terms describing a method of construction such as an “implant” and its derivatives are examples and do not reflect all methods of doping the semiconductor material in an example implementation, which could include vapor or gas phase, solid source, liquid source as well as plasma and beamline implant. Alternative methods are likely and may be used as appropriate in additional and/or alternative arrangements depending on performance, costs and availability, and the like.

The accompanying drawings are incorporated into and form a part of the specification to illustrate one or more example implementations of the present disclosure. Various advantages and features of the disclosure will be understood from the following Detailed Description taken in connection with the appended claims and with reference to the attached drawing Figures in which:

FIG. 1A depicts a top plan view of an IC device including one or more corrugated channel structures where vertically separated body and source contact regions may be provided according to some examples of the present disclosure;

FIGS. 1B-1 to 1B-3 depict cross-sectional views of the IC device shown in FIG. 1A along three sectional planes through a drain region, a channel region and a source/body region, respectively, of the corrugated channel structures;

FIGS. 2A-1 through 2A-3 to FIGS. 2K-1 through 2K-3 depict cross-sectional views of an IC device at various stages of formation in a process flow for fabricating body contact regions and source contact regions in different surfaces of a corrugated channel structure according to an example of the present disclosure; and

FIG. 3 is a flowchart of an IC fabrication method according to some examples of the present disclosure.

### DETAILED DESCRIPTION

Examples of the disclosure are described with reference to the attached Figures where like reference numerals are generally utilized to refer to like elements. The Figures are not drawn to scale and they are provided merely to illustrate examples. Numerous specific details, relationships, and methods are set forth below to provide an understanding of one or more examples. However, it should be understood that some examples may be practiced without such specific details. In other instances, well-known subsystems, components, structures and techniques have not been shown in detail in order not to obscure the understanding of the examples. Accordingly, the examples of the present disclosure may be practiced without such specific components.

Additionally, terms such as “coupled” and “connected,” along with their derivatives, may be used in the following description, claims, or both. It should be understood that these terms are not necessarily intended as synonyms for each other. “Coupled” may be used to indicate that two or more elements, which may or may not be in direct physical or electrical contact with each other, co-operate or interact with each other. “Connected” may be used to indicate the establishment of communication, i.e., a communicative relationship, between two or more elements that are coupled with each other. Further, in one or more examples set forth herein, generally speaking, an element, component or module may be configured to perform a function if the element may be programmed for performing or otherwise structurally arranged to perform that function.

Without limitation, examples of IC devices comprising one or more raised channel structures and the fabrication thereof will be set forth below in the context of improvements in the performance of FinFET devices. Analogous to planar MOSFET devices, FinFETs may also exhibit susceptibility to performance trade-offs such as on-resistance (Rₛₚ) vs. safe operating area (SOA), where SOA may be defined as the voltage and current conditions over which the device can be expected to operate without damage, which in turn may be related to the breakdown voltage of the device, BVDSS. Further, FinFETs are also afflicted with parasitic bipolar effects that may impact the device operation. In both these conditions, internal resistances such as gate-to-body resistance and/or gate-to-source resistance often play an important role.

Examples of the present disclosure recognize these and other related performance constraints and provide a contact region architecture for a FinFET device where low ohmic contact regions for both body and source terminals may be provided on different surfaces of the raised fins in a region proximate to the FinFET's gate by taking advantage of the 3-dimensional topography of the fins. In some arrangements, examples herein may be configured to reduce source path resistance as well as body path resistance in a FinFET by placing the body and source contact regions nearer the gate, and hence the active channel, in surfaces that may be separated in a vertical dimension. Lower source path resistance is expected to reduce the overall device resistance, thereby improving the Rₛₚ performance. Further, lowering of the resistance in the device's body is expected to reduce the bias of a parasitic bipolar junction transistor that snaps back during high current/voltage conditions. Accordingly, the breakdown performance of the device is also expected to be improved. In additional and/or alternative arrangements, only a subset of the fins of a FinFET may be selected for the fabrication of source and/or body contact regions, thereby further reducing the overall contact path resistance. While such examples provide structures and processes that may advantageously help modulate a FinFET's performance trade-offs in a more optimal manner, no particular result is a requirement unless explicitly recited in a particular claim.

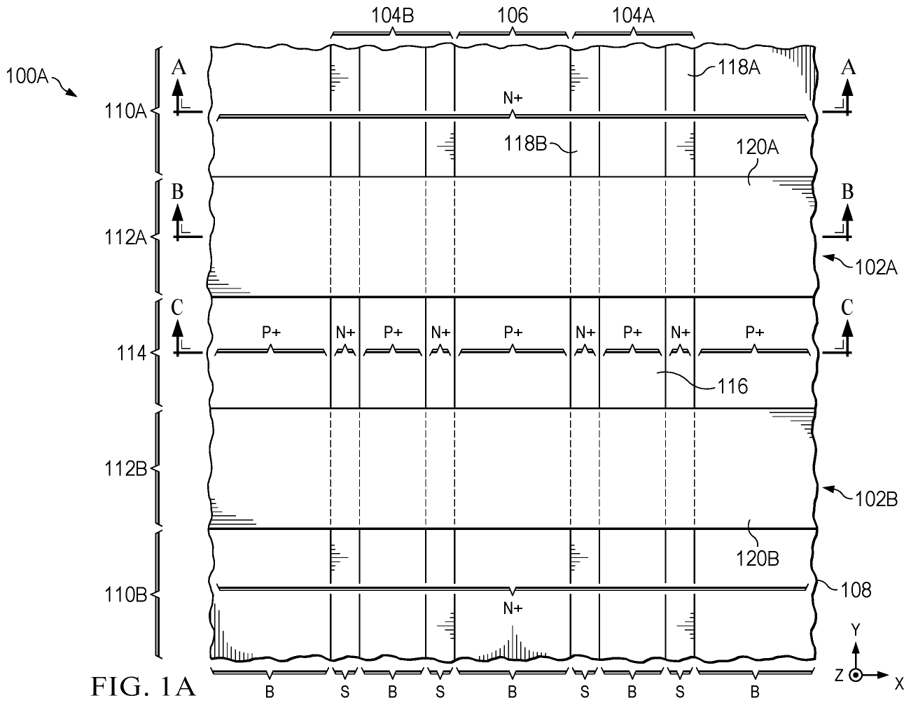

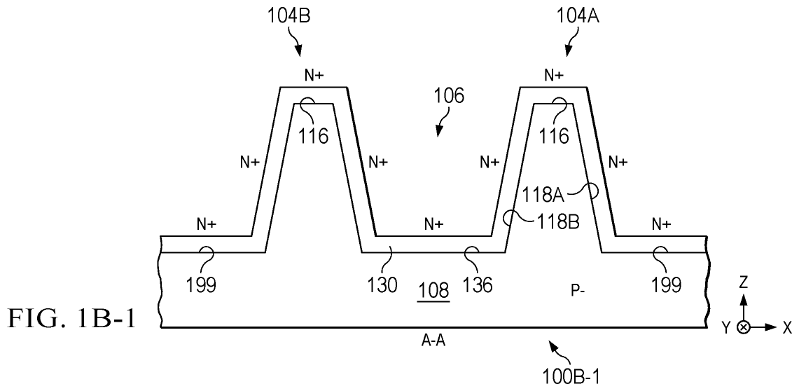

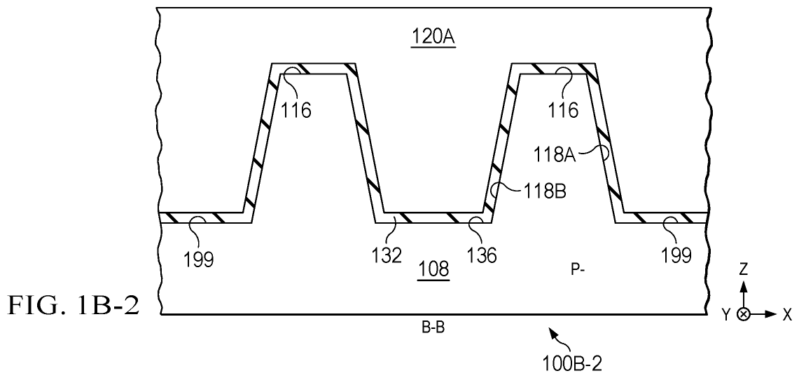

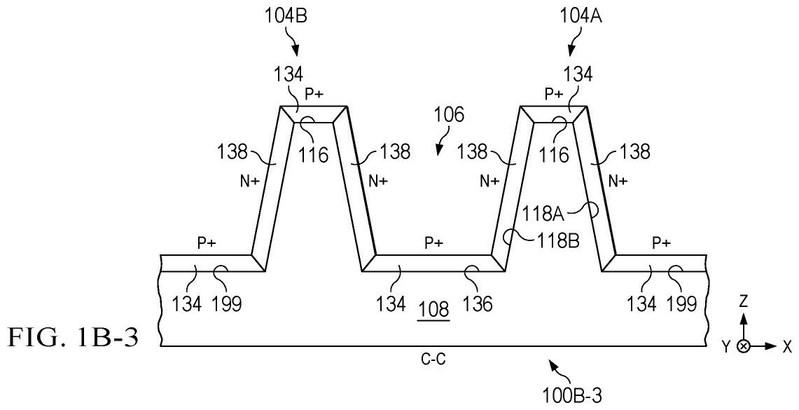

Referring now to the drawing Figures, FIG. 1A depicts a top plan view of an IC device 100A including one or more corrugated channel structures, or “fins”, where vertically separated body and source contact regions may be provided according to some examples of the present disclosure. FIGS. 1B-1 through 1B-3 depict together a constellation of cross-sectional views of the IC device 100A shown in FIG. 1A through different regions of a corrugated channel structure formed according to some examples of the present disclosure. Depending on implementation and application, the example IC device 100A may be representative of any type of standalone FinFET device or a portion of an integrated microelectronic device including one or more FinFETs integrated with various other types of circuitry. In some arrangements, the IC device 100A or at least a portion thereof may be illustrative of devices such as, including but not limited to folded drain extended metal oxide semiconductor (DEMOS) field effect transistor (FET) devices, laterally diffused MOS (LDMOS) FinFET devices, and FinFETs configured for high voltage power applications (e.g., having appropriate breakdown voltage (V_{bd}) and specific on-resistance (Rₛₚ) characteristics), low voltage logic applications, high voltage radio frequency (RF) applications, etc. Further, the IC device 100A may be fabricated in a silicon or other semiconductor material as noted below, e.g., as a bulk FinFET, epitaxial FinFET, silicon-on-insulator (SOI) FinFET, etc., depending on implementation and/or application. In an example arrangement, the IC device 100A may comprise one or more FinFETs, each including a plurality of fins or corrugated channel structures 104A, 104B formed in a semiconductor substrate 108 or a region of the substrate 108, which may comprise any suitable semiconductor material having appropriate conductivity type (e.g., in a bulk material or in a well region, etc.), and has a first conductivity type, e.g., p-type as used in various disclosed examples. In some arrangements, adjacent regions or FinFETs may be disposed in a parallel connection, or alternatively isolated from each other, forming channels that span multiple fins/trenches in a first case and one or more fin channels that are delineated by trenches in a second. Further, adjacent corrugated channel structures of a FinFET may be separated by respective trenches formed therebetween in the substrate 108, e.g., as illustrated by a trench 106 formed between the corrugated channel structures 104A, 104B.

By way of example, a first FinFET 102A and a second FinFET 102B are shown as part of the IC device 100A, where the corrugated channel structures 104A and 104B of each FinFET 102A, 102B may be suitably doped to form a plurality of regions, e.g., a source region, a body region, a channel region, and a drain region, for facilitating the operation of the FinFETs 102A/102B. As will be set forth further below, one or more source and body contact regions of a FinFET device may be formed in a same portion of the corrugated channel structure by leveraging the vertical topography of the corrugated channel structures, e.g., along the Z-axis of a reference 3-dimensional X-Y-Z Cartesian coordinate system with respect to the IC device 100A as shown in FIG. 1A and FIGS. 1B-1 through 1B-3. In some optional arrangements where a drift region is included in an example FinFET, the drift region may be provided between the channel region and the drain contact region and may be disposed under a field plate, with the drift region having the same conductivity type as the drain contact region.

In some examples, appropriate dopant species may be used for doping different surfaces of the corrugated channel structures 104A, 104B of the FinFETs 102A, 102B in different regions thereof. For example, one or more surfaces associated with a portion of the corrugated channel structure, e.g., a top surface of the corrugated channel structure, sidewall surfaces of the corrugated channel structure, and/or a bottom surface of an adjacent trench, may be doped with different species of appropriate conductivity depending on the type of contact region to be formed, e.g., a source contact region or a body contact region. As will be set forth further below, a suitable doping process may be implemented using one or more hard masks in different combinations in conjunction with a beamline implant technique for selectively masking the different surfaces of the corrugated channel structures depending on a desired combination of contact regions according to some examples herein.

As shown in in FIG. 1A, the corrugated channel structures 104A, 104B of FinFET 102A and FinFET 102B extend along a first axis, e.g., the Y-axis of the reference X-Y-Z Cartesian coordinate system, where each corrugated channel structure associated with a particular FinFET may comprise a drain region, a channel region, and a region having both source and body contact regions that are shared between the two FinFETs 102A and 102B. The sequence of source/gate/drain regions with appropriate body regions may be reflected in an array manner in some examples, such that in the Y direction there is a pattern of s/g/d/g/s/g/d/s . . . regions depending on layout. Accordingly, a FinFET, e.g., FinFET 102A, 102B, may be visualized as comprising three corresponding regions or portions that may be doped appropriately in a selective manner. By way of illustration, drain regions 110A and 110B, channel regions 112A and 112B are shown with respect to FinFETs 102A and 102B, respectively, where a source/body region 114 is shared by both FinFETs 102A and 102B. Gate structures 120A and 120B, e.g., comprising a doped polysilicon structure, which may be fabricated in other suitable electrodes or materials according to some additional and/or alternative arrangements, may be provided with respect to FinFETs 102A and 102B, respectively, where the gate structure 120A and 120B may overlap the respective channel regions 112A, 112B, and extend along a second axis, e.g., X-axis, that is orthogonal to the first axis. In the example arrangement shown in FIG. 1A, the two FinFETs 102A and 102B may each be provided as a mirror image of the other, where like components in one FinFET are denoted with the same reference number or initialism as corresponding components in the other FinFET, but with a “b” or “B” appended thereto instead of an “a” or ‘A”, as applicable. Accordingly, the description of one FinFET in the following discussion is equally applicable to the other FinFET, unless otherwise noted, at least for purposes of some examples herein.

Each corrugated channel structure 104A/104B may be formed to have a 3-dimensional topography, e.g., extending vertically along a third axis, Z-axis, for instance, as previously noted, where the corrugated channel structures may include horizontal surfaces, e.g., a top surface 116, as well as non-horizontal surfaces, e.g., a first sidewall surface 118A and a second sidewall surface 118B, as shown in the constellation of views of FIG. 1B-1 through 1B-3. Focusing on FinFET 102A, three cross-sectional views of the IC device 100A along sectional planes A-A, B-B and C-C through the different regions of FinFET 102A are shown in FIGS. 1B-1 through 1B-3, respectively. Sectional view 100B-1 along A-A is illustrative of a cross-section in the drain region 110A of FinFET 102A including the corrugated channel structures 104A and 104B, where all the surfaces of the corrugated channel structures as well as horizontal surfaces adjacent to the sidewall surfaces may be doped with a dopant species having suitable conductivity type and sufficient concentration so as to facilitate an ohmic drain contact region for FinFET 102A. In an example, the dopant species may comprise a second conductivity type that is opposite to the first conductivity type of the substrate 108 over which FinFET 102A is formed. As illustrated in the sectional view 100B-1 of FIG. 1B-1, a heavily doped layer 130 may be conformally formed over the top surfaces 116, sidewall surfaces 118A/118B, a bottom 136 of the trench 106 formed between the adjacent corrugated channel structures 104A and 104B as well as horizontal top surfaces 199 of the semiconductor substrate 108 adjacent to the corrugated channel structures 104A and 104B, which may be provided as respective “terminal fins” of a plurality of corrugated channel structures of a representative FinFET of the IC device 100A in some examples.

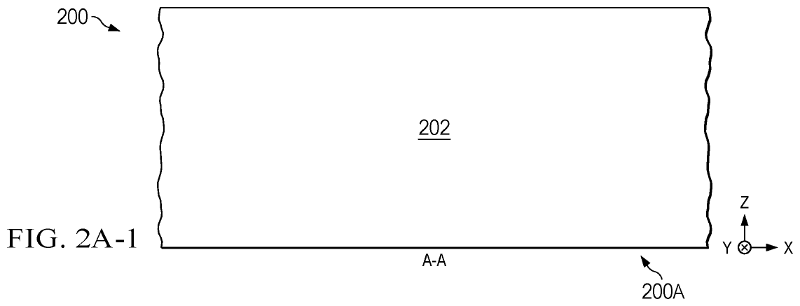

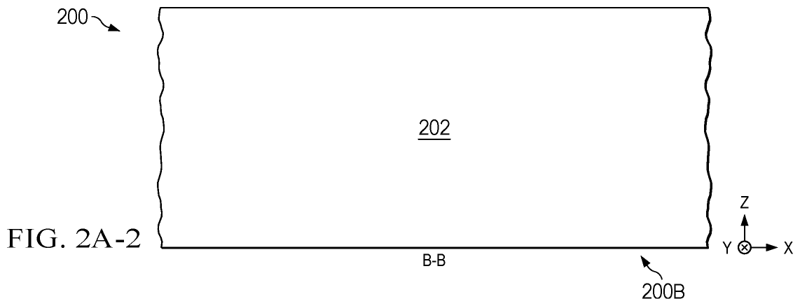

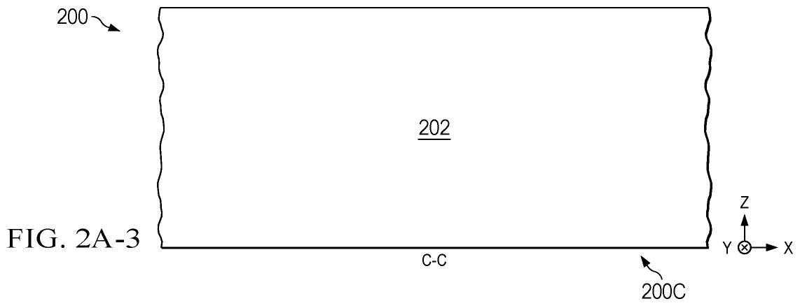

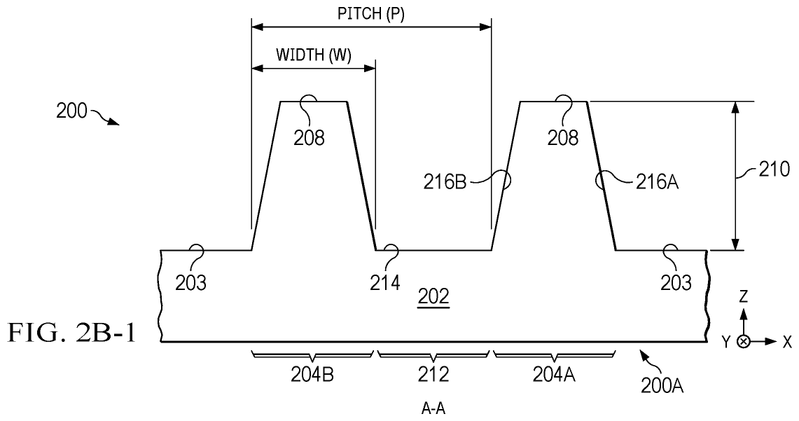

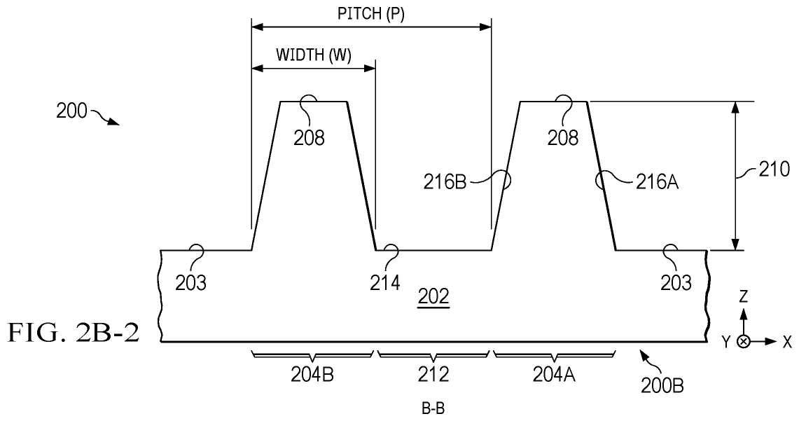

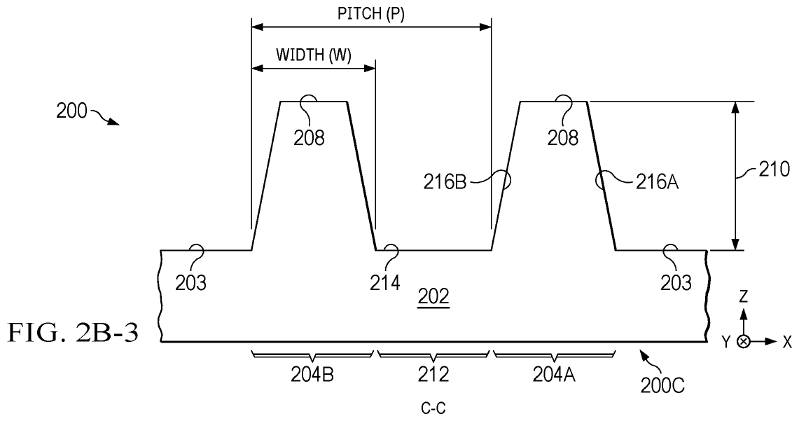

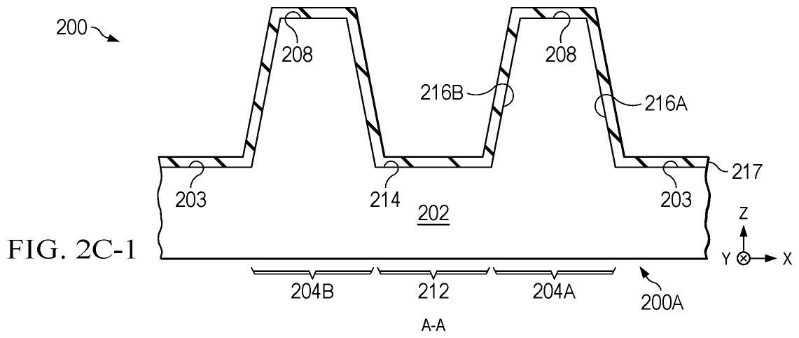

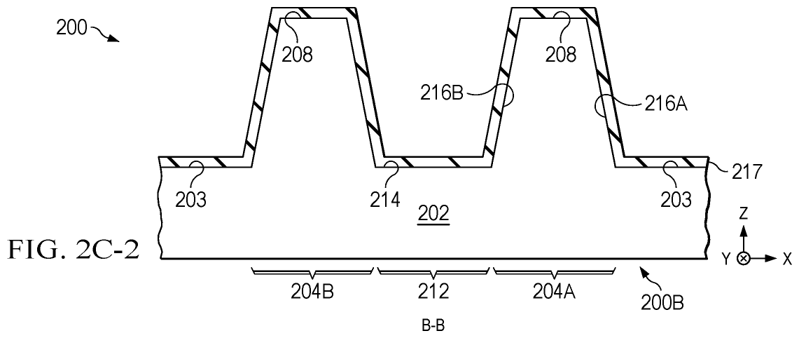

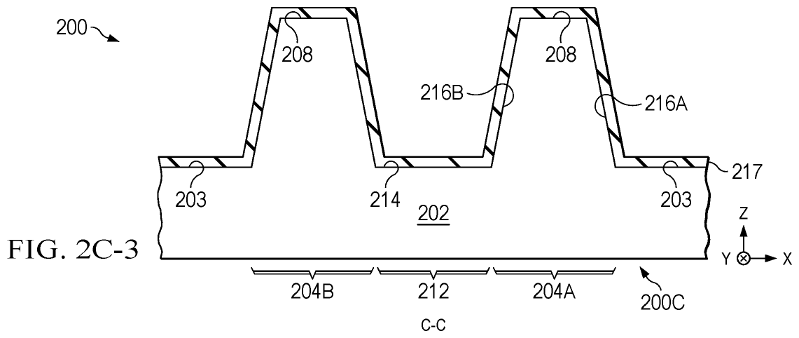

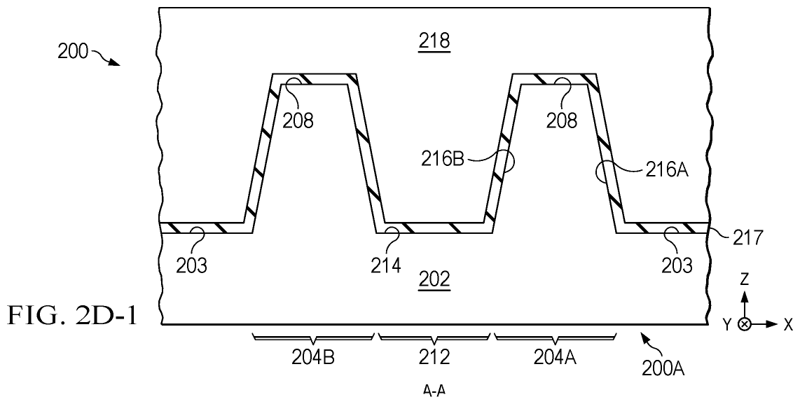

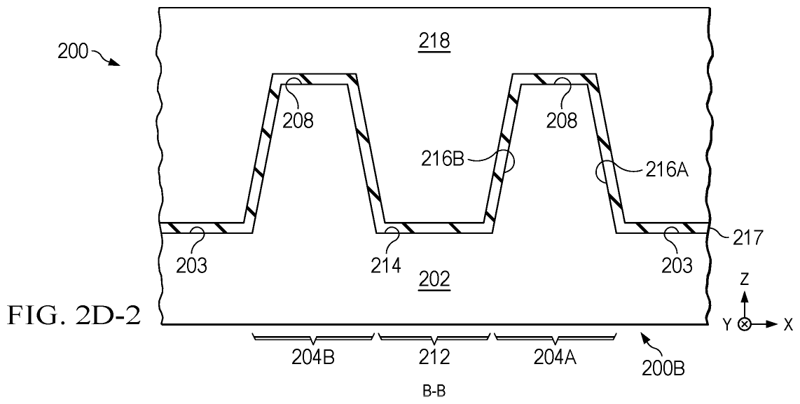

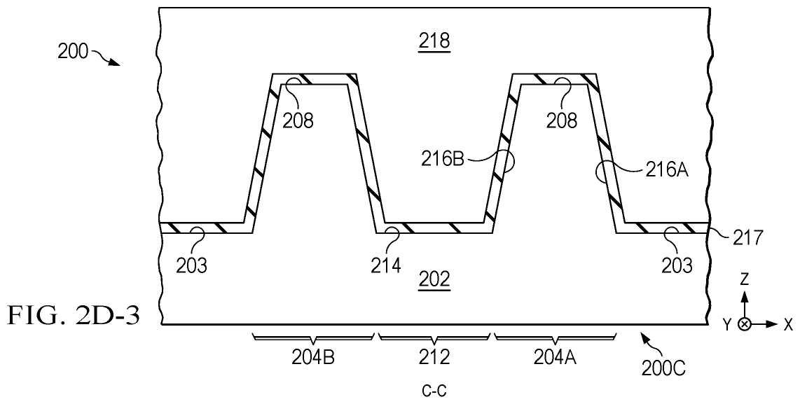

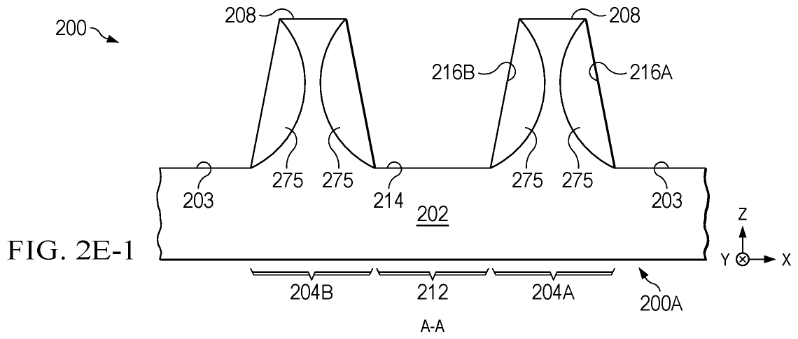

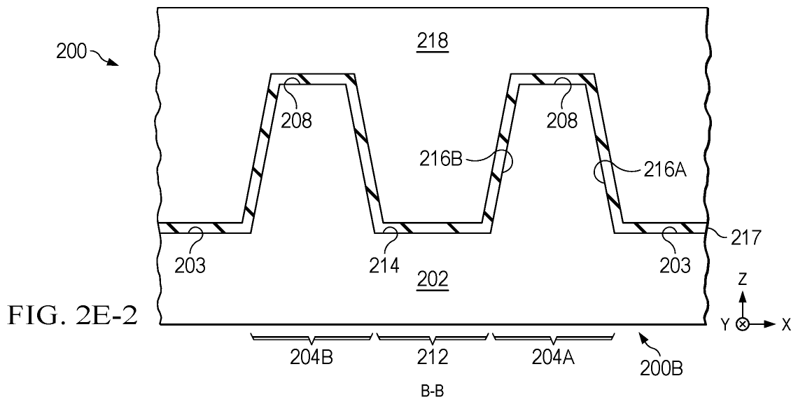

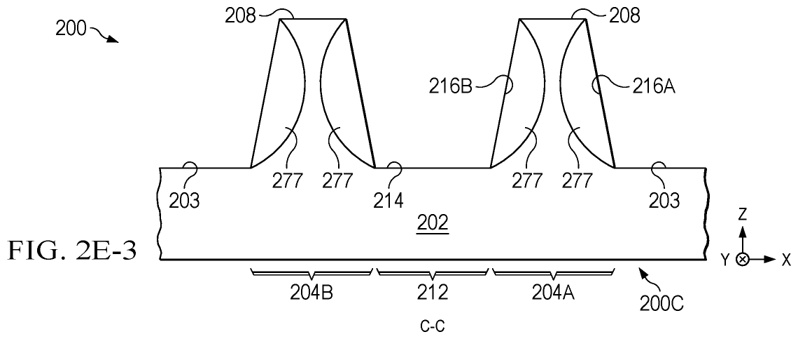

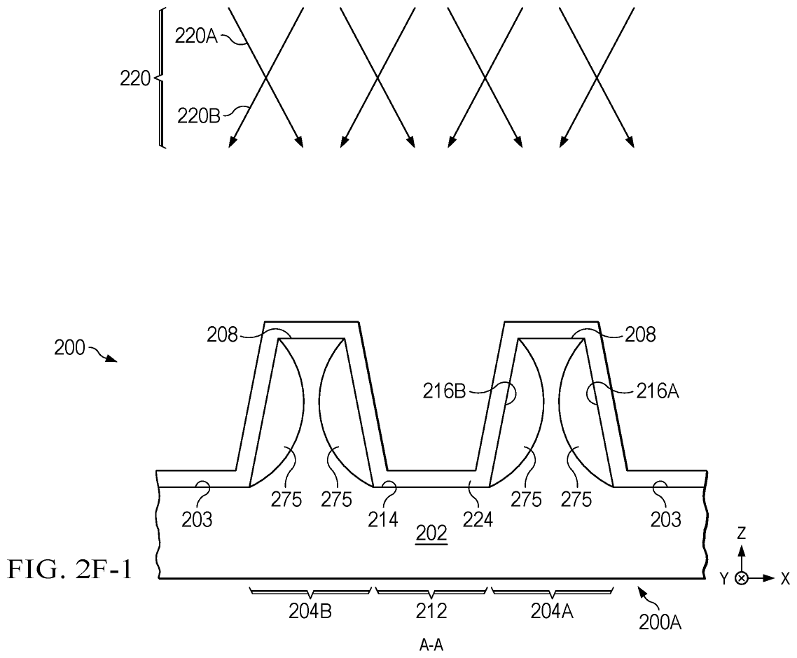

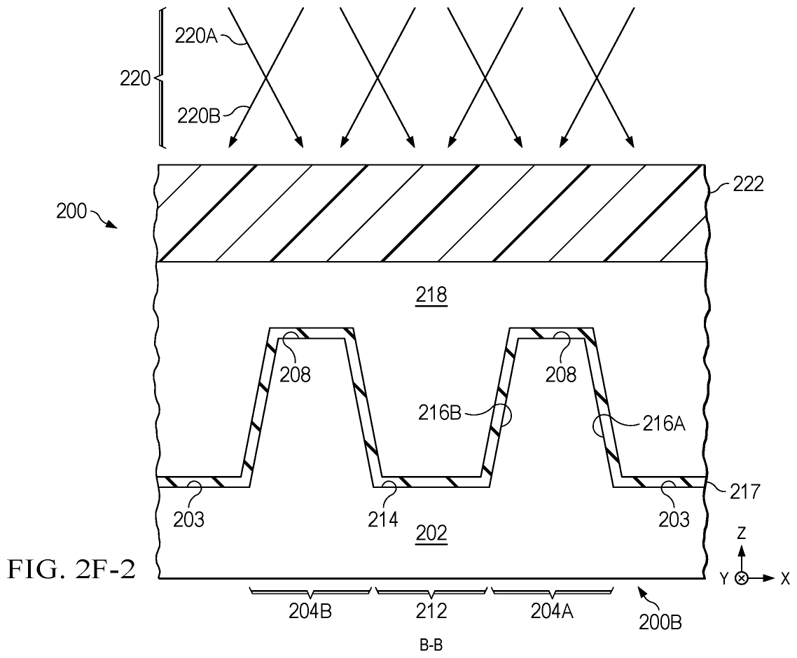

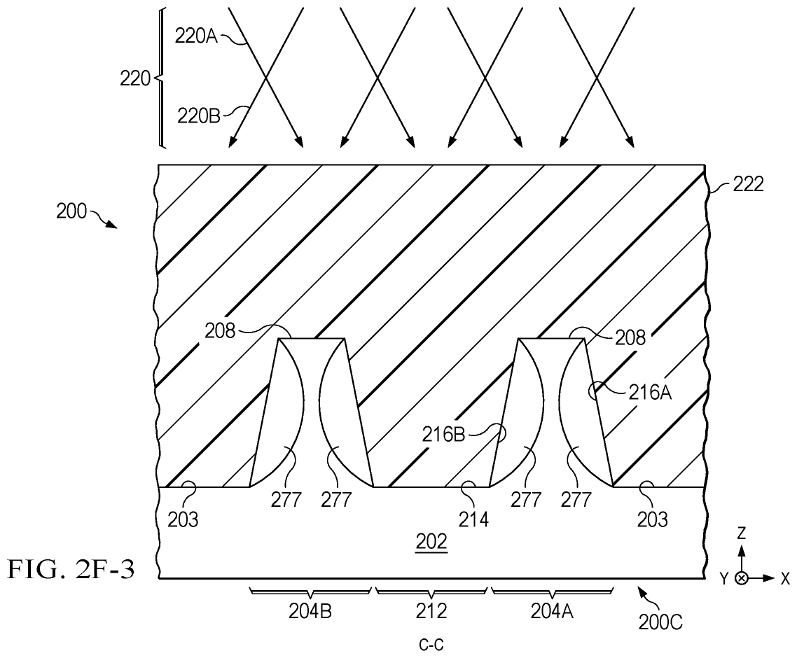

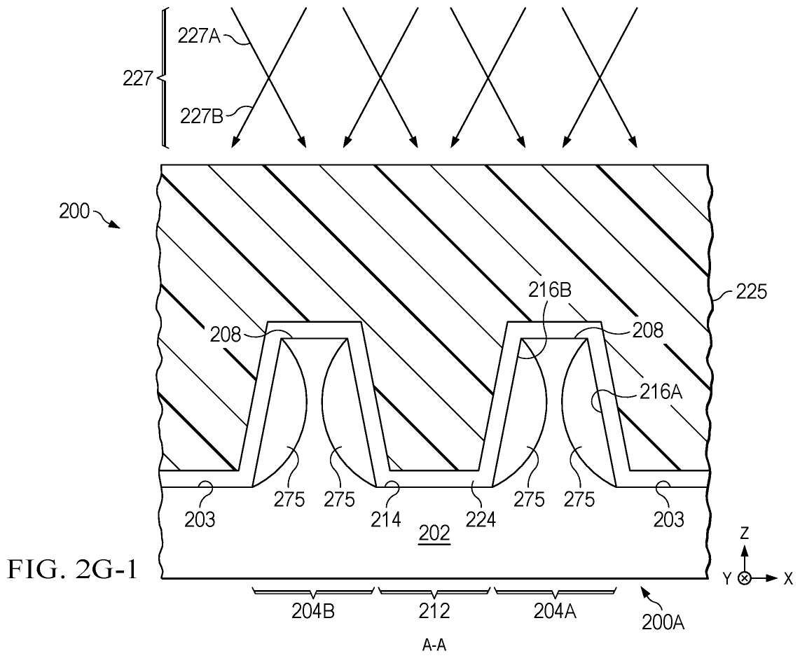

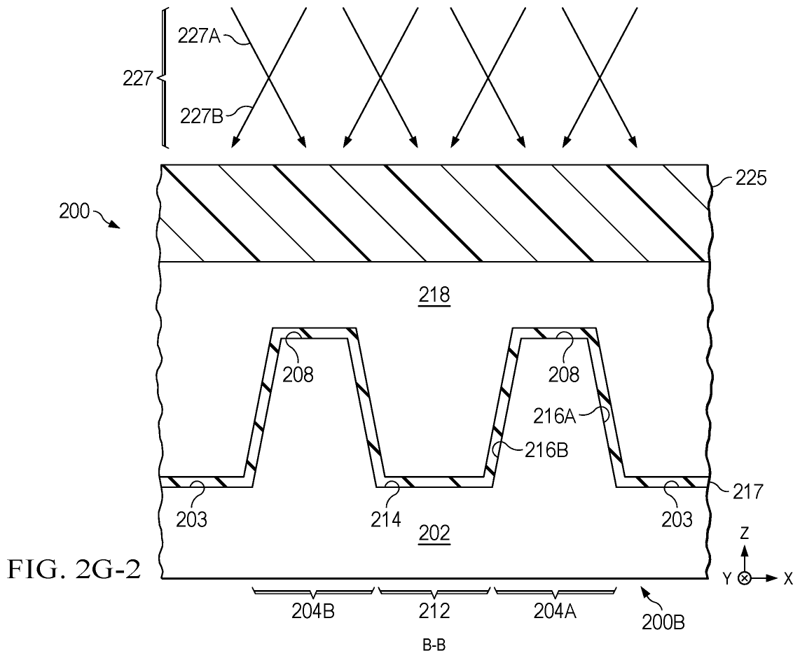

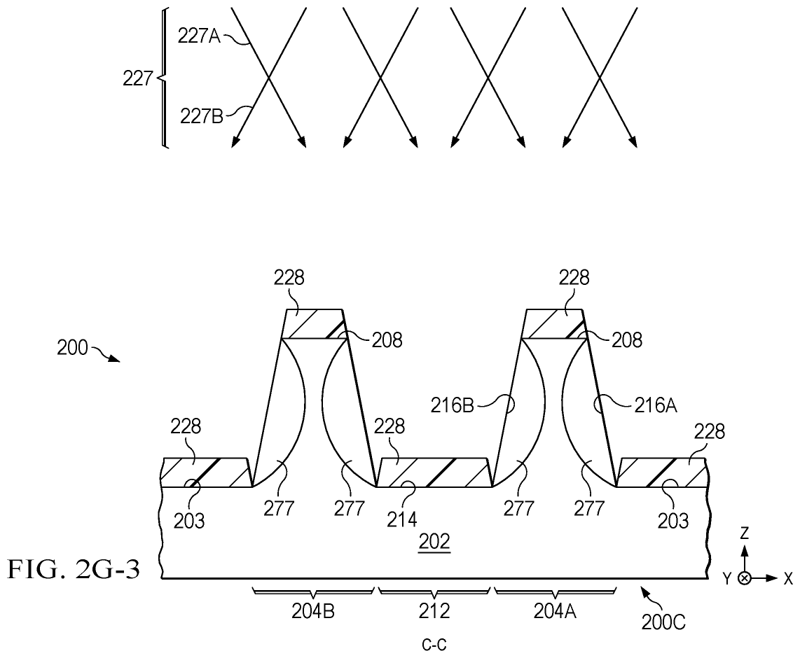

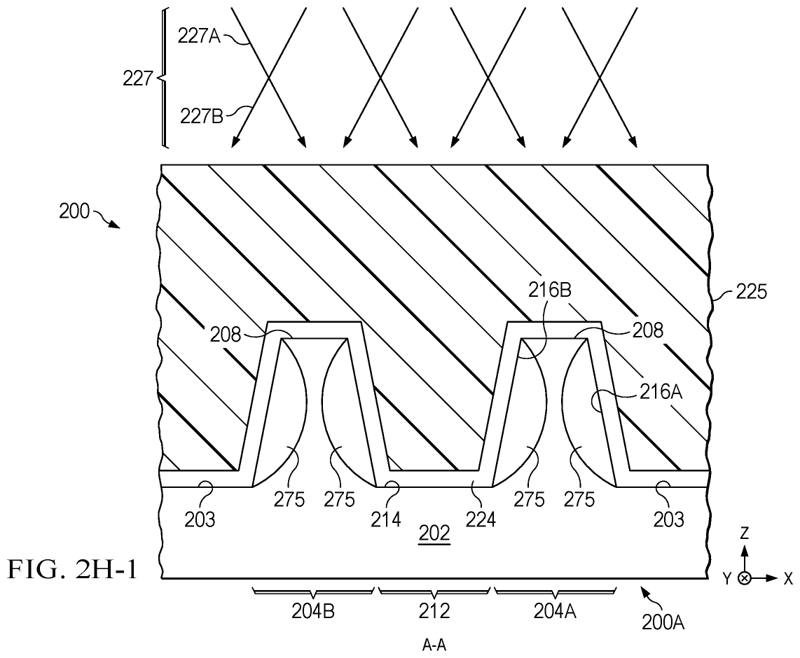

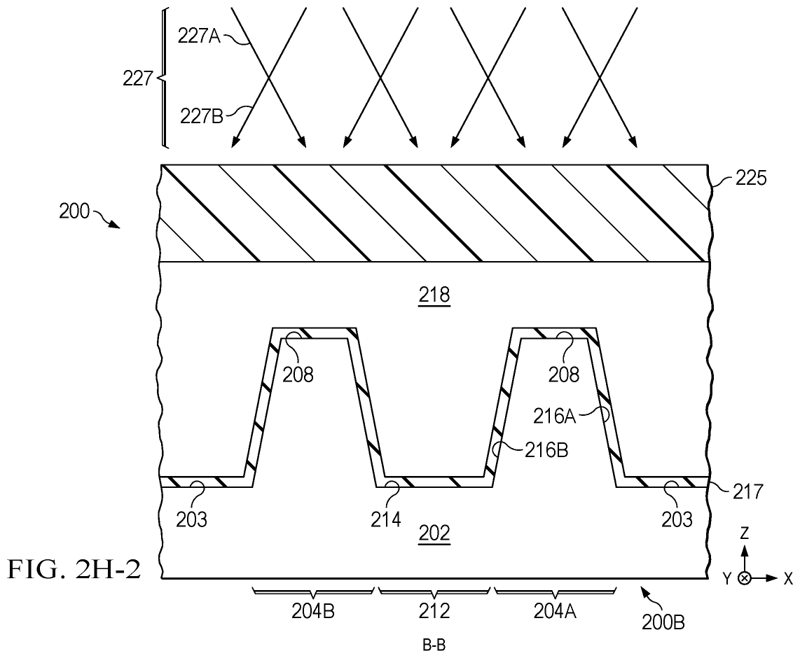

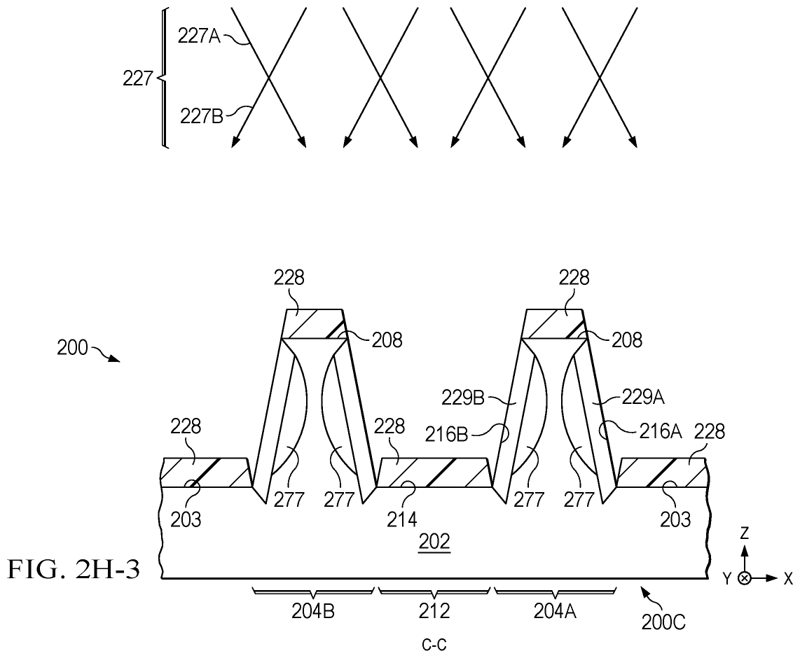

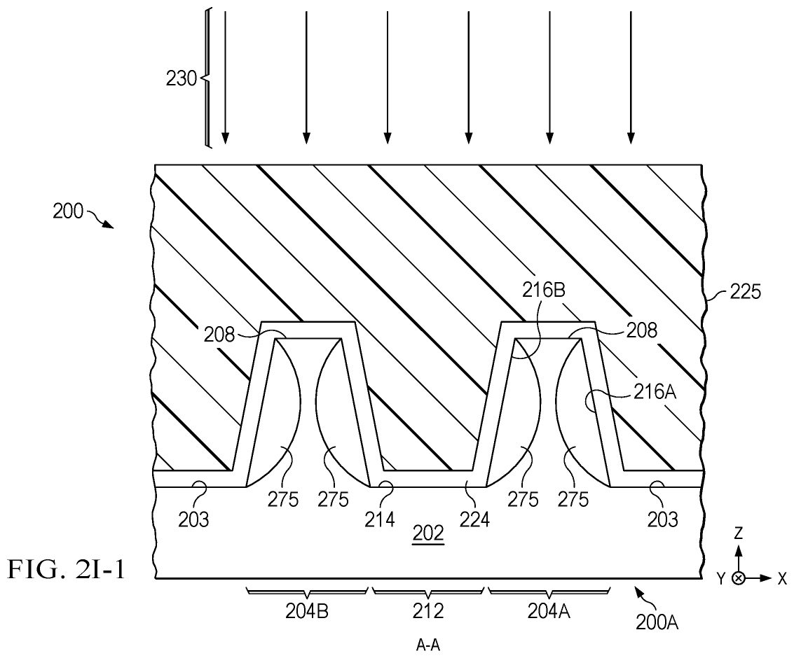

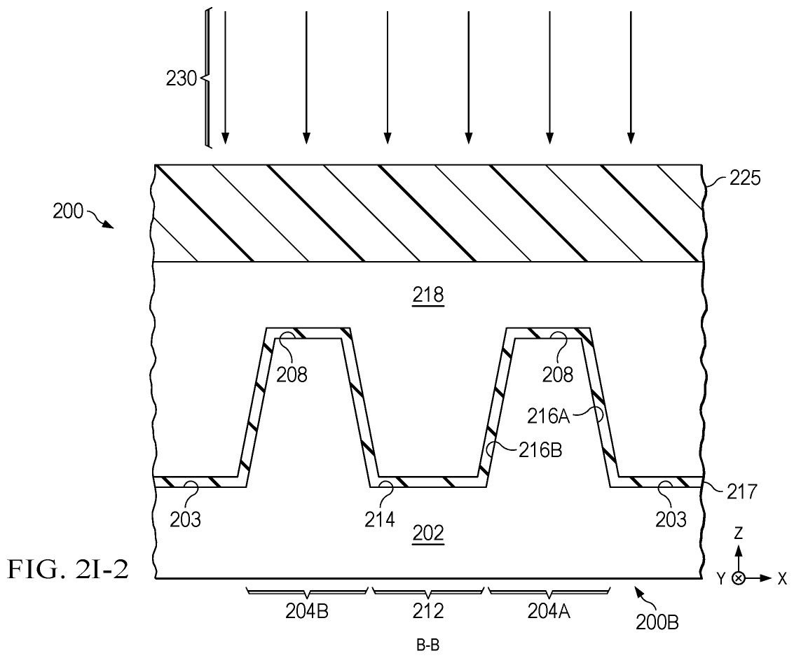

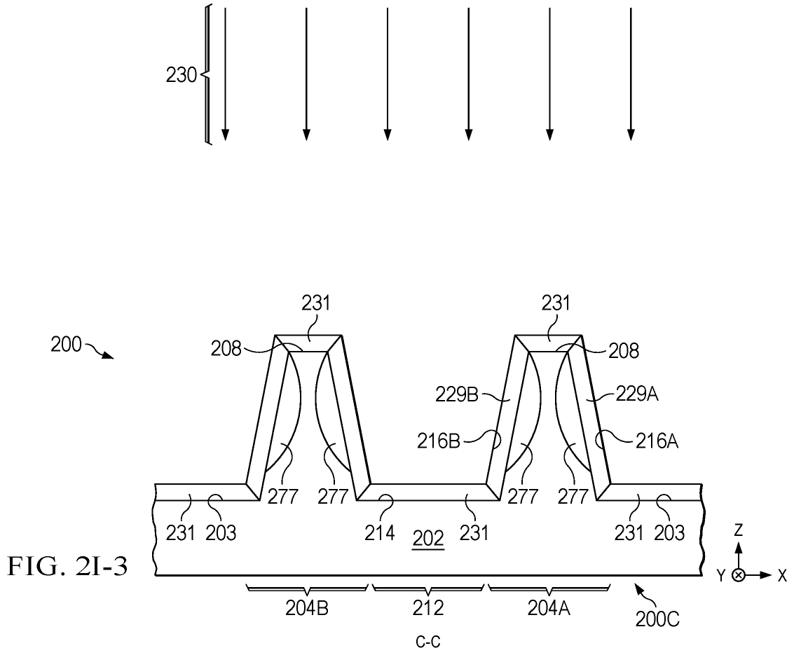

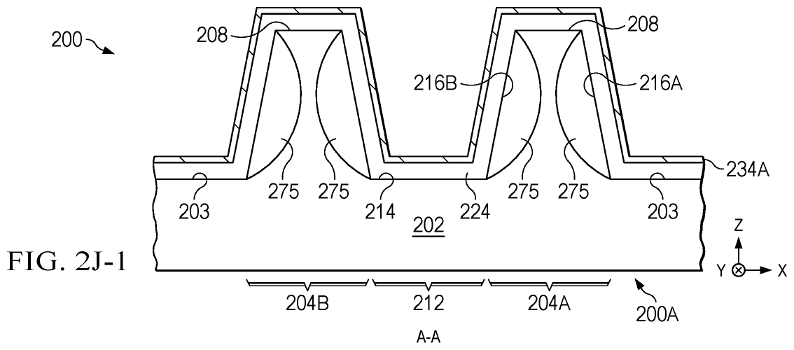

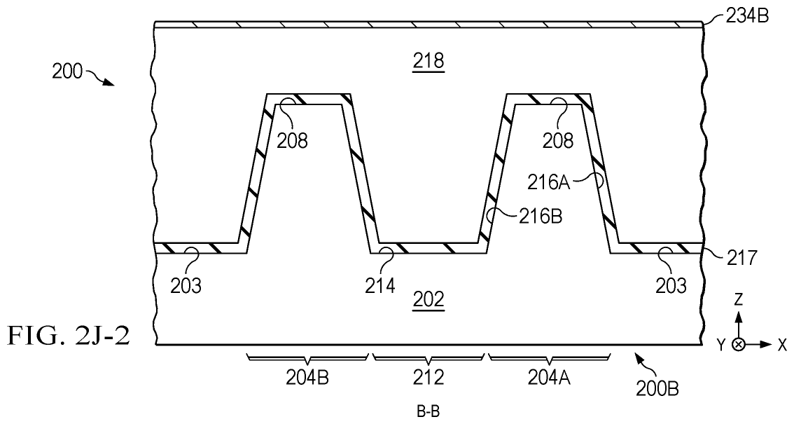

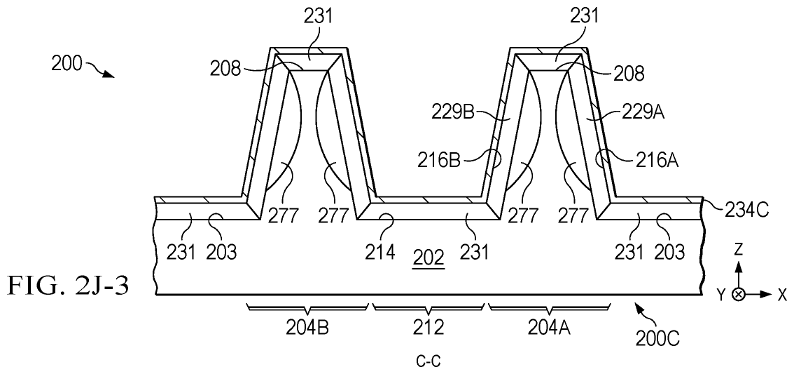

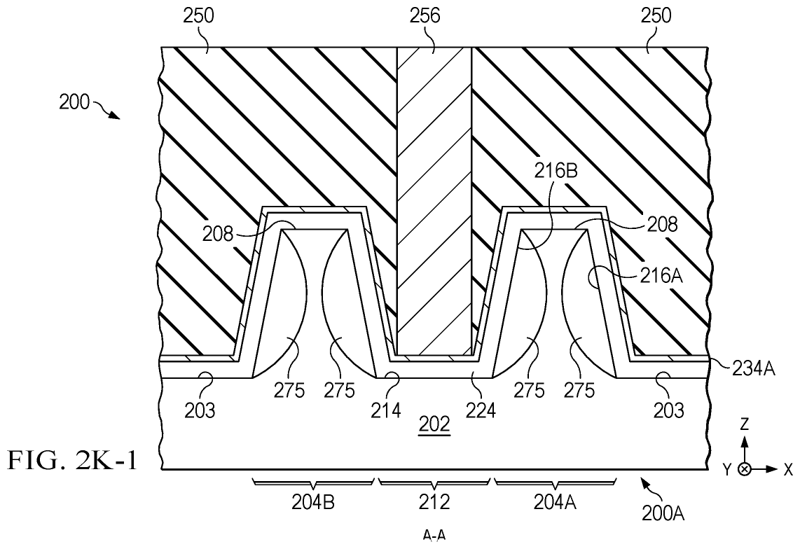

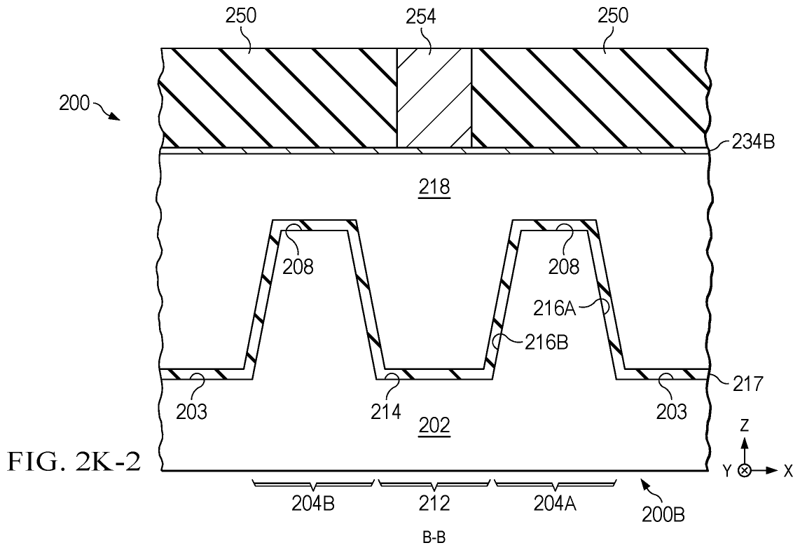

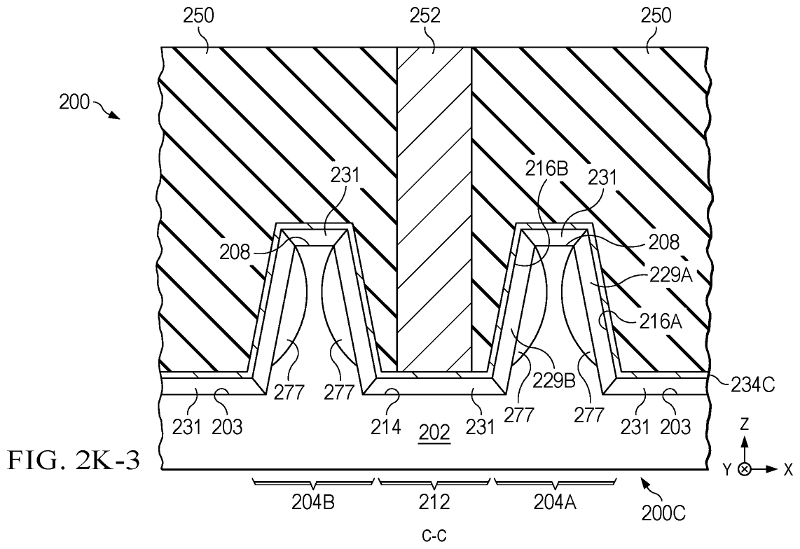

Continuing to refer to FIGS. 1A and 1B-2, sectional view 100B-2 along B-B is illustrative of a cross-section of the channel region 112A in the FinFET 102A including the corrugated channel structures 104A and 104B, where all the surfaces of the corrugated channel structures as well as horizontal surfaces adjacent to the sidewall surfaces 116A, 116B may be overlaid with a gate dielectric layer 132 of suitable thickness and composition. In an example arrangement, a planarized gate structure 120A, e.g., polysilicon, may be formed over the gate dielectric layer 132. As will be set forth further below, because there may be no need for diffusion region formation for contacts in this portion of FinFET 102A, the corresponding regions of the corrugated channel structures 104A/104B of the IC device 100A may be suitably masked while implanting appropriate dopant species for forming the drain, source and/or body contact regions of FinFET 102A.

Sectional view 100B-3 is illustrative of a cross-section in the source/body region 114 of FinFET 102A including the corrugated channel structures 104A and 104B, where different surfaces of the corrugated channel structures as well as horizontal surfaces adjacent to the sidewall surfaces may be selectively doped with different dopant species having suitable conductivity type(s) and sufficient concentration(s) so as to facilitate ohmic body contact regions and ohmic source contact regions for FinFET 102A. In one example, the dopant species for forming contact regions may comprise dopants of the first conductivity type, but at a higher concentration than used for doping the substrate 108, which may be selectively implanted only in one or more of the top surfaces 116, the bottom 136 of the trench 106 and/or the horizontal top surfaces 199 of the semiconductor substrate 108 adjacent to the corrugated channel structures 104A and 104B, for forming what may be referred to as body contact regions with respect to the body region of FinFET 102A. Accordingly, one or more body contact regions 134 are illustrated in the sectional view 100B-3 of FIG. 1B-3. In one example, the dopant species for forming contact regions with respect to the source of FinFET 102A (also referred to as source contact regions) may comprise a dopant species having suitable conductivity type and sufficient concentration that facilitates an ohmic source contact region for FinFET 102A, which may be selectively doped only in one or more sidewall surfaces 118A, 118B of the respective corrugated channel structures 104A, 104B. For example, the dopant species for forming source contact regions may comprise a second conductivity type that is opposite to the first conductivity type of the semiconductor substrate 108, where the second conductivity type may be similar to that of the dopant species used for forming the drain contact layer 130. As illustrated in FIG. 1B-3, one or more source contact regions 138 may be selectively formed in the sidewall surfaces 118A/118B by appropriately masking the remaining surfaces of the IC device 100A including the horizontal surfaces that are configured for forming body contact regions as set forth above.

While the foregoing example of FIG. 1B-3 illustrates an arrangement where the body contact regions are formed in the horizontal surfaces and the source contact regions are formed in the sidewall surfaces of the corrugated channels structures 104A/104B in the source/body region 114, numerous permutations and combinations of the body and source contact region configurations may be implemented in additional and/or alternative arrangements. For example, the location of the body and source contact regions may be interchanged or switched in some arrangements so that the body contact regions may be formed in the sidewall surfaces while the source contact regions may be formed in the horizontal surfaces of FinFET 102A. Further, only a portion or subset of a plurality of corrugated channel structures may be used for forming body and source contact regions in some examples. In additional and/or alternative variations, the subset of the corrugated channel structures selected for forming the body and source contact regions may be evenly spaced in some arrangements, e.g., the corrugated channel structures selected for the formation of body and source contact regions may be separated by a same number of the corrugated channel structures not selected.

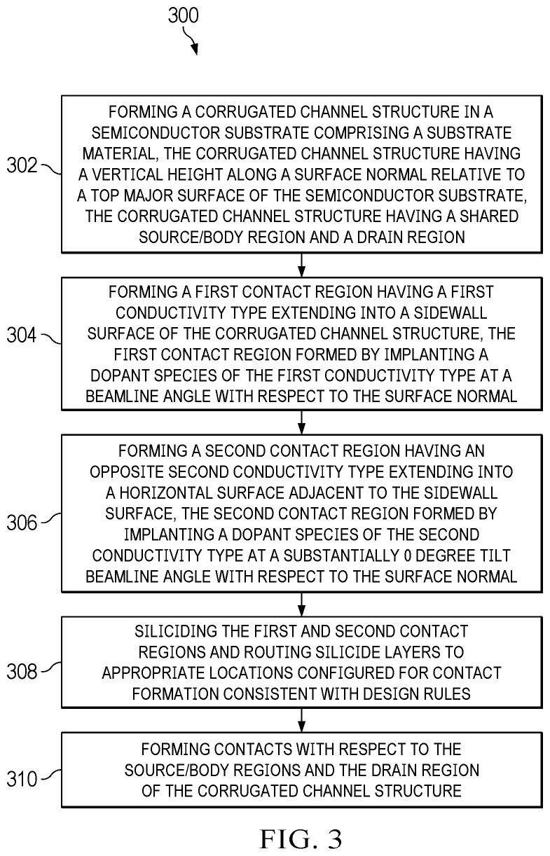

FIGS. 2A-1 through 2A-3 to FIGS. 2K-1 through 2K-3 depict cross-sectional views of an IC device 200 including a FinFET at various stages of formation in a process flow for fabricating body contact regions and source contact regions in different surfaces of a corrugated channel structure according to an example of the present disclosure. For purposes of some examples, the IC device 200 may also be referred to as a FinFET device. As set forth herein, views depicted in FIGS. 2A-1 through 2A-3 to FIGS. 2K-1 through 2K-3 each illustrate a constellation of three cross-sectional views representing the progression of three different portions or regions of the FinFET device, e.g., a drain region, a channel region, and a source/body region, respectively, as the IC device 200 is processed in a fabrication flow. In other words, the views shown in FIGS. 2A-1 to 2K-1 refer to the cross-sectional views of the drain region, the views shown in FIGS. 2A-2 to 2K-2 refer to the cross-sectional views of the channel region, and the views shown in FIGS. 2A-3 to 2K-3 refer to the cross-sectional views of the source/body region of the IC device 200 at different stages of the fabrication flow. By way of illustration, reference numbers 200A, 200B and 200C shown in these constellations FIGS. 2A-1 to 2K-1, FIGS. 2A-2 to 2K-2 and FIGS. 2A-3 to 2K-3, roughly correspond to the cross-sectional views of the IC device 100A along the planes A-A, B-B and C-C taken in the drain region, the channel region, and the source/body region, respectively, as shown in FIGS. 1A and 1B-1 through 1B-3. Accordingly, the reference numbers 200A, 200B and 200C in FIGS. 2A-1 to 2K-1, FIGS. 2A-2 to 2K-2 and FIGS. 2A-3 to 2K-3, refer to the drain regions, the channel regions and the source/body regions, respectively, of a plurality of corrugated channel structures to be formed over or in a suitable substrate as part of the FinFET device 200. It is to be noted upon reference hereto that various types of FinFETs may be fabricated using a variety of process flows and the examples of the present disclosure are not limited to any particular FinFET implementation. Accordingly, not all fabrication stages involved in a FinFET process flow are depicted here so as not to obscure the understanding of the examples of the present disclosure.

Specifically referring to FIGS. 2A-1 to 2A-3, the IC device 200 comprising a semiconductor substrate 202 at a representative early front-end-of-line (FEOL) fabrication stage is depicted, where one or more corrugated channel structures or fins of a FinFET may be formed in subsequent stages as part of a flow depending on the technology, process node and/or product application of the IC device 200. In some arrangements, the semiconductor substrate 202 may be part of a larger semiconductor substrate (which may include other electronic circuitry and components, not shown in the Figures) that is suitably doped depending on the type of FinFET to be fabricated in the semiconductor substrate 202. Depending on application, an example FinFET implementation may be based on metal oxide semiconductor (MOS) technologies, complementary metal oxide semiconductor (CMOS) technologies, double-diffused metal oxide semiconductor (DMOS) technologies, etc., including analog, digital and/or mixed signal device designs. In some examples, a combination of semiconductor technologies may be implemented, wherein different technologies suitable for respective types of product design may be integrated within the same chip or IC device, e.g., linear BiCMOS or LBC (a bipolar-CMOS combination technology where MOS and bipolar technology may be used for analog functions and CMOS may be used for digital logic design), BCD (a bipolar-CMOS-DMOS combination technology where DMOS may be integrated within the IC device for power and high-voltage portions that also has analog and digital portions), and the like. Accordingly, without being limited to a particular implementation, the semiconductor substrate 202 may comprise a portion of a semiconductor process wafer, e.g., an IC die, that may be processed to include to any combination of epitaxial layers, buried layers, laterally diffused extensions, N-wells, P-wells, deep wells, shallow wells, reduced surface field (RESURF) layers formed over the dielectric layers of SOI substrates, etc. Further, the example semiconductor substrate 202 may include various isolation structures for dielectrically isolating the constituent layers, regions, well structures, etc., using a variety of isolation techniques, e.g., shallow trench isolation (STI), local oxidation of silicon (LOCOS), etc. which may be formed at or during any suitable FEOL stage(s) integrated within a flow as set forth herein.

In some examples, the semiconductor substrate 202 depicted in the early fabrication stage of FIGS. 2A-1 to 2A-3 may have received various types of doping steps, e.g., one or more depositions, epitaxial steps or implantations comprising threshold voltage adjustment implants (VT implants), deep isolation implants (e.g., NWELL/PWELL implants), ground plane (GP) implants, which may also be used to isolate devices from one another in some examples, and/or anti-punchthrough (APT) implants, etc. Whereas the semiconductor substrate 202 may predominantly comprise suitably doped silicon as substrate material in some examples, other semiconductor materials such as, Ge, SiGe, GaAs, SiC, GaN, other Group III-V materials, etc., may be used in some implementations, where one or more epitaxial layers or single-crystal layers may be formed or provided as part of the semiconductor substrate 202 in some arrangements.

Without limitation, the semiconductor substrate 202 may comprise a semiconductor material of a first conductivity type, e.g., p-type, which may be provided as part of a FinFET fabrication flow described in U.S. Pat. Nos. 10,978,559; 11,152,506; 11,437,49; 11,508,842 and U.S. Patent Appl. Publ. No. 2022/0123130, each of which is incorporated by reference in its entirety for all purposes, which may be individually and/or collectively referred to as “incorporated disclosures”. FIGS. 2B-1 to 2B-3 illustrate a fabrication stage where a plurality of corrugated channel structures, e.g., fins 204A, 204B, have been formed in the semiconductor substrate 202. In an example implementation, the adjacent corrugated channel structures 204A, 204B may be either connected in parallel or separated by respective troughs or trenches 212 formed therebetween, e.g., each having a bottom 214 forming a horizontal surface proximate to the adjacent corrugated channel structures 204A, 204B. In some examples, the trenches 212 may be formed by a suitable anisotropic etch, e.g., reactive ion etch (RIE) process using fluorine radicals, in association with appropriately patterned masking, as is set forth in one or more incorporated disclosures. By way of example, the trenches 212 may have an average depth of 300 nanometers (nm) to 1200 nm or more, which corresponds to an average vertical height 210 of the corrugated channel structures 204A, 204B, along a surface normal relative to a top major surface, e.g., surface 203, of the semiconductor substrate 202 after the formation of the corrugated channel structures 204A, 204B. As illustrated, the corrugated channel structures 204A, 204B may each be visualized as having a top surface 208 and sidewall surfaces 216A, 216B, and in some cases adjacent trench bottoms 214, where the sidewall surfaces 216A, 216B may be provided as respective lateral portions of a corresponding corrugated channel structure 204A/B. In some arrangements, the sidewall surfaces 216A, 216B may be slanted or angled such that the respective corrugated channel structure 204A/204B may be formed as a tapered structure where an upper portion including the top surface 208 may have a width that is about 40% to 50% of the height 210 of the corrugated channel structure 204A/B. In some arrangements, a lower portion of the corrugated channel structure 204A/B may have a width that is about 50% to 60% of the height 210 of the corrugated channel structure 204A/B proximate to a bottom 214 of the adjacent trench 212. Accordingly, the sidewall surfaces 216A, 216B may be sloped around 80° to 89° with respect to a horizontal surface, e.g., the bottom 214 and/or the top major surface 203, in some examples. In some arrangements, representative widths (W) and pitches (P) of the “fin-and-trench” sections may be varied generally or individually. Whereas the depth of the trenches is usually consistent, it may vary with trench width. Sidewall angles and shapes may vary from the examples shown in the drawing Figures and may be optimized for different process/device attributes.

Depending on implementation, the semiconductor substrate 202 including the corrugated channel structures 204A, 204B may be doped with suitable dopants to form or adjust one or more charge balance regions and drain drift regions (not shown in FIGS. 2B-1 to 2B-3) in the appropriate regions of the corrugated channel structures 204A, 204B, e.g., the drain region 200A, the channel region 202B, and the source/body region 200C, as set forth in the incorporated disclosures. The formation of a gate dielectric layer 217 and a gate layer 218 (e.g., comprising polysilicon) over the different regions of the corrugated channel structures 204A, 204B are illustrated in FIGS. 2C-1 through 2C-3 and FIGS. 2D-1 through 2D-3, respectively, followed by the removal of the gate layer 218 from the drain region 200A and the source/body region 200C of the corrugated channel structures 204A, 204B, as shown in FIGS. 2E-1 through 2E-3. In some arrangements, the gate dielectric layer 217 may be formed by a thermal oxidation or other process and may primarily include a silicon dioxide or other layer having a thickness of about 3 nm to 10 nm. In some arrangements, nitrogen may be introduced into the gate dielectric layer 217 by exposing the gate dielectric layer 217 to a nitrogen-containing plasma. In some arrangements, the gate dielectric layer 217 may include high dielectric constant (high k) material, such as hafnium oxide, zirconium oxide, or tantalum oxide. In some arrangements, the gate layer 218 may have an initial thickness that may be dependent on the desired final thickness of the gate layer 218 remaining in the channel region 200B, e.g., 100 nm to 200 nm, after suitable etch-backs and polishing (e.g., chemical-mechanical polishing/planarization (CMP)). Depending on implementation, the gate layer 218 may comprise furnace-deposited polysilicon, in-situ doped polysilicon, amorphous polysilicon, etc. Further, suitable dopants may be implanted or otherwise introduced into the drain region 200A as well as the source/body regions 200C for providing appropriate levels of dopants in the drain regions as well as source and body regions with respect to the FinFET device 200. In an NMOS example, the source and drain regions may be formed by implanting dopants of n-type (e.g., phosphorus, arsenic, and antimony, etc.) whereas a body region may comprise a portion of the substrate material having p-type dopants (e.g., boron, gallium, and indium, etc.). Without any limitation, junction profiles 275 and 277 shown in FIGS. 2E-1 and 2E-3 are illustrative of the doped drain and sources of the corrugated channel structures 204A, 204B in the corresponding regions thereof, respectively.

In some implementations, a drain contact region may be formed in the drain region 200A, e.g., as a heavily doped conformal layer 224 that may be formed over one or more surfaces including the sidewalls 216A/216B and the top surface 208 of the corrugated channel structures 204A/204B as well as the bottom 214 of the trench 212 and the top surface 203 of the semiconductor substrate 202 in the drain region 200A, as depicted in FIG. 2F-1. In some implementations, the channel region 200B and the source/body region 200C may be covered by a suitably patterned mask 222 (e.g., a photoresist and anti-reflection material, such as a bottom anti-reflection coat (BARC)), which may be formed by a photolithographic process, e.g., as illustrated in FIGS. 2F-2 and 2F-3. The exposed drain region 200A may be implanted using a line-of-sight implant technique, e.g., an angled beamline implant 220, that may involve one or more beamline tilt angles for implanting dopant species into each sidewall surface 216A, 216B in multiple implant steps, e.g., implants 220A, 220B, involving appropriate dopant species, implant energies, concentrations, and the like. In some examples, the dopant species may comprise a second conductivity type opposite to the first conductivity type of the semiconductor substrate 202, where the second conductivity type dopants may be implanted and activated to achieve profiles with an average net concentration greater than or equal to about 5×10¹⁸ cm⁻³ to 5×10²⁰ cm⁻³ (e.g., having a degenerate doping concentration) in order to effectuate a low resistance ohmic contact to the drain region 200A of the FinFET device 200.

FIGS. 2G-1 through 2G-3 to FIGS. 2I-1 through 2I-3 depict a series of fabrication stages where different surfaces associated with the corrugated channel structures 204A/204B of the FinFET device 200 may be selectively implanted or otherwise doped with dopant species of different conductivity types to form body contact and source contact regions in a portion of the corrugated channel structures 204A/204B, e.g., the source/body region 200C, while masking the remaining regions 200A and 200B using one or more masking layers. Depending on which portions of the exposed surfaces in the source/body region 200C (e.g., the horizontal surfaces including the top surfaces 208 of the corrugated channel structures 204A/204B, the bottom 214 of the trench 212 and the top major surfaces 203 of the semiconductor substrate 202, and non-horizontal surfaces including the sidewall surfaces 216A, 216B of the corrugated channel structures 204A/204B) are utilized for which type of contact regions (e.g., body contact regions or source contact regions), different configurations of body and source contact regions may be formed according to the examples herein by implementing appropriately patterned masks for selectively masking either the horizontal surfaces or the non-horizontal surfaces. Further, only the surfaces associated with a subset of a plurality of corrugated channel structures may be utilized for forming the body and/or source contact regions in some examples, which may be implemented using various combinations of layout and masking schemes. In some arrangements, therefore, the body and/or source contact regions may be formed in one or more surfaces of every N^{th} corrugated channel structure (e.g., every other, every third, every fourth, etc.) selected from the plurality of corrugated channel structures. In some arrangements, a selected corrugated channel structure may comprise one of a proper subset of the plurality of corrugated channel structures where the selected corrugated channel structures of the proper subset are separated by a same number of corrugated channel structures not in the proper subset. In some arrangements, the body contact and/or source contact regions may be implanted as continuous strips or in segments, which may be oriented relative to the corrugated channel structures in a number of ways. Various permutations and/or combinations of body and source contact regions may therefore be configured according to the examples herein depending on implementation, product type and design considerations in optimizing or modulating performance tradeoffs, e.g., SOA vs. Rₛₚ tradeoff, in a FinFET application. Without limitation, an example may include forming one or more body contact regions in the horizontal surfaces associated with at least a portion of the corrugated channel structures whereas one or more source contact regions may be formed in the sidewall surfaces of the corresponding corrugated channel structures. Another non-limiting example may include forming one or more source contact regions in the horizontal surfaces associated with at least a portion of the corrugated channel structures and forming one or more body contact regions in the sidewall surfaces of the corresponding corrugated channel structures.

To facilitate the formation of contact regions only in the source/body region 200C of the corrugated channel structures 204A and 204B, the drain region 200A and the channel region 200B may be covered by a suitably patterned mask layer 225 in some examples, as depicted in FIGS. 2G-1/2G-2 to FIGS. 2I-1/2I-2. Further, to form the contacts only in the sidewall surfaces of the (selected) corrugated channel structures, e.g., corrugated channel structures 204A and 204B, the horizontal surfaces of the corrugated channel structures 204A and 204B in the source/body region 200C may be masked by a suitable hard mask, e.g., hard mask 228 covering the top surfaces 208 of the corrugated channel structures 204A and 204B, the bottom 214 of the trench 212 and the top surface 203 of the semiconductor substrate 202, as shown in FIGS. 2G-3 and 2H-3. In some examples, the hard mask 228 may comprise an oxide hard mask formed in a dual mask flow involving an initial conformal nitride hard mask (not shown in the Figures) over which the oxide hard mask is formed and subsequently anisotropically etched (e.g., by an RIE process) to expose the sidewall surfaces 216A, 216B of the corrugated channel structures 204A/204B while the horizontal surfaces remain covered. Details regarding an example dual mask flow are described in U.S. patent application Ser. No. 18/496,697, filed Oct. 27, 2023 (referred to as the '697 patent application), which is incorporated by reference herein for all purposes. A line-of-sight implant process 227, e.g., a beamline implant process, may be used to implant appropriate dopants in the sidewall surfaces 216A, 216B at one or more tilt angles, as exemplified by implants 227A, 227B in FIGS. 2G-1 through 2G-3 and FIGS. 2H-1 through 2H-3. The implanted dopant species may be annealed or otherwise activated to form contact regions 229A, 229B (e.g., a first contact region) in the respective sidewall surfaces 216A, 216B (shown in FIG. 2H-3). In one arrangement, the implanted dopant species may comprise p-type dopants (e.g., for forming body contact regions). In another arrangement, the implanted dopant species may comprise n-type (e.g., for forming source contact regions). Similar to the drain contact region layer 224, the dopant profiles in the sidewall contact regions 229A, 229B may have an average net concentration greater than or equal to about 5×10¹⁸ cm⁻³ to 5×10²⁰ cm⁻³, e.g., a degenerate doping concentration, in order to effectuate low resistance ohmic contacts to the either a source or a body of the FinFET device 200 depending on the conductivity types involved.

The oxide hard mask 228 may be subsequently removed from the horizontal surfaces of the corrugated channel structures 204A and 204B in the source/body region 200C (e.g., using a dilute hydrofluoric acid (HF) deglaze process) while the drain region 200A and the channel region 200B remain covered by the mask layer 225. A substantially vertical implant 230, e.g., having a zero tilt angle within a range (e.g., 0°+2°), may be implemented for implanting the exposed horizontal surfaces in the source/body region 200C as shown in FIGS. 2I-1 through 2I-3, thereby forming a contact region (e.g., a second contact region) therein. The sidewall surfaces 216A, 216B receive little or no secondary doping from the vertical implant process as they are substantially parallel to the angle of incidence of the implant 230, thereby maintaining about the same net concentrations of the dopant species previously introduced in the angled beamline implants 220. Thereafter, the dopant species of the corrugated channel structures 204A, 204B as well as the remaining portions and regions of the semiconductor substrate 202 may be activated using one or more annealing steps (not specifically shown in Figures). In some examples, an anneal process may comprise a rapid thermal anneal (RTA) process at around 1000° C. to 1200° C. for about 10 to 15 seconds, without limitation, similar to the examples set forth in the '697 patent application, incorporated by reference hereinabove.

As shown in FIGS. 2J-1 through 2J-3, suitable metal silicide layers may be formed over the drain region 200A, the channel region 200B and the source/body region 200C of the FinFET device 200, respectively, for facilitating contact formation with a metal interconnect in subsequent fabrication stages. By way of illustration, a metal silicide 234A is formed over the doped conformal layer 224 in the drain region 200A of the FinFET device 200. Likewise, a metal silicide 234B is formed over the gate layer 218 in the channel region 200B and a metal silicide 234C is formed over the contact regions formed in the horizontal surfaces and the sidewall surfaces of the FinFET device in the source/body region 200C. In an example implementation, the metal silicides 234A-234C may be formed by forming a metal layer, not explicitly shown, on the respective contact regions or the gate structure, where the metal layer may include one or more metals suitable for forming the metal silicide, such as titanium, cobalt, nickel, or platinum, without limitation. In some examples, the metal layer may be formed by a sputter process, an ion plating process, or metal organic chemical deposition (MOCVD) process, to provide more uniform coverage of the corrugated surfaces in the drain and source/body regions of the FinFET device 200.

After silicidation, a pre-metal dielectric (PMD) layer 250 is formed over the different regions of the FinFET device 200, extending over the semiconductor substrate 202, as shown in FIGS. 2K-1 through 2K-3. In some examples, the PMD layer 250 may comprise one or more (sub) layers of varying compositions and thicknesses. In some arrangements, the PMD layer 250 may be formed as a dielectric stack including, by way of example, a PMD liner, formed on the FinFET device 200, a PMD main layer, formed on the PMD liner, and a cap layer, formed on the PMD main layer. The PMD liner may include one or more layers of silicon dioxide, silicon nitride, or silicon oxynitride, and may be formed by a plasma enhanced chemical vapor deposition (PECVD) process or a low pressure chemical vapor deposition (LPCVD) process. The PMD main layer may include primarily silicon dioxide, silicon dioxide with hydrogen, phosphosilicate glass (PSG), or borophosphosilicate glass (BPSG), by way of example, and may be formed by a PECVD process, an atmospheric pressure CVD (APCVD) process, a high density plasma (HDP) process, or a high aspect ratio process (HARP) using ozone. The cap layer may include silicon nitride, silicon carbide, silicon carbide nitride, or other material suitable for a stop layer for a CMP process. The cap layer may be formed by a PECVD process, for example. Thereafter, one or more contacts may be formed on the metal silicides 234A-234C in the respective regions of the FinFET device 200. For purposes of illustration, contacts 256 are formed for contacting with the drain contact regions 224 in the drain region 200A, contacts 254 are formed for contacting with the gate layer 218 in the channel region 200B, and contacts 252 are formed for contacting with the contact regions 231 and 229A/229B, which may be a combination of body contact regions and source contact regions that may be shunted together in some examples herein. Additional details regarding metal silicidation, PMD layers and contact formation may be found in one or more incorporated disclosures referenced hereinabove.

It should be noted that the metal silicides 234A-234C and/or associated contacts 256, 254, 252 are merely representative in the foregoing examples. Some additional and/or alternative examples may include source silicide 234C, drain silicide 234A and/or gate silicide 234B routed to separate terminals outside the view of the figures, e.g., FIGS. 2J-1 through 2J-3 and FIGS. 2K-1 through 2K-3, to provide device terminals conforming to various contact design rules depending on application.

FIG. 3 is a flowchart of an IC fabrication method 300 according to some examples of the present disclosure. At block 302, a corrugated channel structure may be formed in a semiconductor substrate comprising a substrate material, where the corrugated channel structure may have a vertical height along a surface normal relative to a top major surface of the semiconductor substrate. As set forth above, the corrugated channel structure may be comprised of a shared source/body region and a drain region. At block 304, a first contact region having a first conductivity type may be formed, where the first contact region extends into a sidewall surface of the corrugated channel structure. In some arrangements, the first contact region may be formed by doping the sidewall surface with a dopant species of the first conductivity type, e.g., by implanting the dopant species at a beamline angle with respect to the surface normal. A second contact region may be formed as set forth in block 306, where the second contact region may have an opposite, second conductivity type and extends into a horizontal surface adjacent to the sidewall surface. In some arrangements, the second contact region may be formed by doping the horizontal surface with a dopant species of the second conductivity type, e.g., by implanting the dopant species at a zero tilt beamline angle with respect to the surface normal. As previously set forth, the first contact region may be a body contact region and the second contact region may be a source contact region in some examples. In some additional and/or alternative examples, the first contact region may be a source contact region and the second contact region may be a body contact region. Further, a drain contact region may also be formed by suitable doping, e.g., with a dopant species having the same conductivity type of the dopant species used for forming the source contact region, in a same beam implant step or in a separate implant step (e.g., in an implant step prior to forming the source contact region). Thereafter, the contact regions may be silicided and routed as needed to suitable locations configured for contact formation consistent with applicable design rules (block 308). At block 310, various contacts may be formed in orifices defined in a PMD layer disposed over the corrugated channel structure, where the contacts may be operable to provide electrical connectivity with respect to the source/body regions and the drain region of the corrugated channel structure.

While various examples of the present disclosure have been described above, they have been presented by way of example only and not limitation. Numerous changes to the disclosed examples can be made in accordance with the disclosure herein without departing from the spirit or scope of the disclosure. Thus, the breadth and scope of the present disclosure should not be limited by any of the above described examples. Rather, the scope of the disclosure should be defined in accordance with the claims appended hereto and their equivalents.

For example, in this disclosure and the claims that follow, unless stated otherwise and/or specified to the contrary, any one or more of the layers set forth herein can be formed in any number of suitable ways, such as with spin-on techniques, sputtering techniques (e.g., Magnetron and/or ion beam sputtering), (thermal) growth techniques or deposition techniques such as chemical vapor deposition (CVD), physical vapor deposition (PVD), PECVD, LPCVD, or atomic layer deposition (ALD), etc. As another example, silicon nitride may be a silicon-rich silicon nitride or an oxygen-rich silicon nitride. Silicon nitride may contain some oxygen, but not so much that the materials dielectric constant is substantially different from that of high purity silicon nitride. Still further, whereas example FinFETs are depicted with subsurface fins, e.g., where the fins are formed by etching into a substrate for creating trenches that separate the resulting fins, aspects of the present disclosure may also be implemented in other FinFET architectures, e.g., including where the fins are formed or grown over a substrate as a set of protruding fins extending from the substrate's surface.

In at least some additional or alternative implementations, the functions/acts described in the blocks may occur out of the order shown in the flowcharts. For example, two blocks shown in succession may in fact be executed substantially concurrently or the blocks may sometimes be executed in the reverse order, depending upon the functionality/acts involved. Moreover, the functionality of a given block of the flowcharts and/or block diagrams may be separated into multiple blocks and/or the functionality of two or more blocks of the flowcharts and/or block diagrams may be at least partially integrated. Also, some blocks in the flowcharts may be optionally omitted. Furthermore, although some of the diagrams include arrows on communication paths to show a primary direction of communication, it is to be understood that communication may occur in the opposite direction relative to the depicted arrows. Finally, other blocks may be added/inserted between the blocks that are illustrated.

The order or sequence of the acts, steps, functions, components or blocks illustrated in any of the flowcharts and/or block diagrams depicted in the drawing Figures of the present disclosure may be modified, altered, replaced, customized or otherwise rearranged within a particular flowchart or block diagram, including deletion or omission of a particular act, step, function, component or block. Moreover, the acts, steps, functions, components or blocks illustrated in a particular flowchart may be inter-mixed or otherwise inter-arranged or rearranged with the acts, steps, functions, components or blocks illustrated in another flowchart in order to effectuate additional variations, modifications and configurations with respect to one or more processes for purposes of practicing the teachings of the present disclosure. Likewise, although various examples have been set forth herein, not all features of a particular example are necessarily limited thereto and/or required therefor.

At least some portions of the foregoing description may include certain directional terminology, such as, “upper”, “lower”, “top”, “bottom”, “left-hand”, “right-hand”, “front side”, “backside”, “vertical”, “horizontal”, etc., which may be used with reference to the orientation of some of the Figures or illustrative elements thereof being described. Because components of some examples can be positioned in a number of different orientations, the directional terminology is used for purposes of illustration and is in no way limiting. Likewise, references to features referred to as “first”, “second”, etc., are not indicative of any specific order, importance, and the like, and such references may be interchanged, depending on the context, implementation, etc. Further, the features of examples described herein may be combined with each other unless specifically noted otherwise.

Although various implementations have been shown and described in detail, the claims are not limited to any particular implementation or example. None of the above Detailed Description should be read as implying that any particular component, element, step, act, or function is essential such that it must be included in the scope of the claims. Where the phrases such as “at least one of A and B” or phrases of similar import are recited or described, such a phrase should be understood to mean “only A, only B, or both A and B.” Reference to an element in the singular is not intended to mean “one and only one” unless explicitly so stated, but rather “one or more.” In similar fashion, phrases such as “a plurality” or “multiple” may mean “one or more” or “at least one”, depending on the context. All structural and functional equivalents to the elements of the above-described implementations are expressly incorporated herein by reference and are intended to be encompassed by the claims appended below.

What is claimed is:

1. A method of fabricating an integrated circuit (IC), comprising:
forming a corrugated channel structure over a semiconductor substrate comprising a substrate material, the corrugated channel structure having a vertical height along a surface normal relative to a top major surface of the semiconductor substrate; and
forming a first contact region having a first conductivity type extending into a sidewall surface of the corrugated channel structure and a second contact region having an opposite second conductivity type extending into a horizontal surface adjacent to the sidewall surface.

2. The method as recited in claim 1, wherein the first contact region is a body contact region and the second contact region is a source contact region.

3. The method as recited in claim 1, wherein the first contact region is a source contact region and the second contact region is a body contact region.

4. The method as recited in claim 1, wherein the horizontal surface is a bottom of a trench between the corrugated channel structure and an adjacent corrugated channel structure.

5. The method as recited in claim 1, wherein the horizontal surface is a top surface of the corrugated channel structure.

6. The method as recited in claim 1, wherein the first contact region is formed by implanting a dopant species of the first conductivity type at a beamline tilt angle with respect to the surface normal.

7. The method as recited in claim 1, wherein the second contact region is formed by implanting a dopant species of the second conductivity type at a substantially 0° tilt angle with respect to the surface normal.

8. The method as recited in claim 1, wherein the corrugated channel structure extends above a top surface of the semiconductor substrate.

9. The method as recited in claim 1, wherein a top surface of the corrugated channel structure is at or below a top surface of the semiconductor substrate.

10. The method as recited in claim 1, wherein the corrugated channel structure has a p-type body region and the second contact region is p-type.

11. An integrated circuit (IC), comprising:
a corrugated channel structure over a semiconductor substrate having a top major surface with a surface normal; and
a first contact region having a first conductivity type extending into a sidewall surface of the corrugated channel structure and a second contact region having an opposite second conductivity type extending into a horizontal surface adjacent to the sidewall surface.

12. The IC as recited in claim 11, wherein the corrugated channel structure is one of a plurality of corrugated channel structures separated by respective trenches formed between adjacent corrugated channel structures, the horizontal surface being a bottom of a respective trench.

13. The IC as recited in claim 11, wherein the first contact region is a source contact region formed in the sidewall surface of the corrugated channel structure, and the second contact region is a body contact region formed in a top surface of the corrugated channel structure or in a bottom of a trench between the corrugated channel structure and an adjacent corrugated channel structure.

14. The IC as recited in claim 13, wherein the body contact region contains a dopant species implanted at a substantially 0° tilt angle with respect to the surface normal.

15. The IC as recited in claim 13, wherein the source contact region contains a dopant species implanted at one or more beamline tilt angles with respect to the surface normal.

16. The IC as recited in claim 11, wherein the first contact region is a body contact region formed in the sidewall surface the corrugated channel structure, and the second contact region is a source contact region formed in a top surface of the corrugated channel structure or in a bottom of a trench between the corrugated channel structure and an adjacent corrugated channel structure.

17. The IC as recited in claim 16, wherein the source contact region contains a dopant species implanted at a substantially 0° tilt angle with respect to the surface normal.

18. The IC as recited in claim 16, wherein the body contact region contains a dopant species implanted at one or more beamline tilt angles with respect to the surface normal.

19. The IC as recited in claim 11, wherein the corrugated channel structure is one of a plurality of corrugated channel structures separated by respective trenches formed between adjacent corrugated channel structures, the first contact region is one of a plurality of first contact regions each formed in the sidewall surface of a respective one of the corrugated channel structures, and the second contact region is one of a plurality of second contact regions each formed in a top surface of a respective one of the corrugated channel structures and in a bottom of a trench adjacent to a corresponding one of the corrugated channel structures.

20. The IC as recited in claim 17, wherein the corrugated channel structure is one of a proper subset of a plurality of corrugated channel structures, and the first contact region is one of a plurality of first contact regions each formed in the sidewall surface of a respective one of the proper subset of corrugated channel structures.

21. The IC as recited in claim 20, wherein the corrugated channel structures of the proper subset are separated by a same number of corrugated channel structures not in the proper subset.
